(19) United States
(12) Patent Application Publication
(10) Pub. No.: US 2020/0243121 A1
(43) Pub. Date: Jul. 30, 2020

(54) NON-VOLATILE MEMORY AND PROGRAM METHOD THEREOF

(71) Applicant: MACRONIX International Co., Ltd., Hsinchu (TW)

(72) Inventors: Chu-Yung Liu, Changhua County (TW); Hsing-Wen Chang, Miaoli County (TW); Yung-Hsiang Chen, Taipei City (TW); Yao-Wen Chang, Hsinchu County (TW)

(73) Assignee: MACRONIX International Co., Ltd., Hsinchu (TW)

(21) Appl. No.: 16/262,770

(22) Filed: Jan. 30, 2019

(51) Int. Cl. G11C 7/10; G11C 8/08; G11C 7/12

(52) U.S. Cl. CPC G11C 7/1096; G11C 7/12; G11C 8/08

(57) ABSTRACT

A non-volatile memory and a program method thereof are provided. The program method includes: selecting a programmed word line, where the programmed word line has a plurality of segments respectively corresponding to a plurality of bit lines; providing a program voltage to a voltage receiving end of the programmed word line, and sequentially transmitting the program voltage to the segments; respectively providing a plurality of bit line voltages to the bit lines at a plurality of enable time points and turning on a string selection switch at a setting time point; and setting voltage values of the bit line voltages according to the segments corresponding to the bit lines, respectively, or setting the enable time points according to the segments corresponding to the bit lines, or setting the setting time point according to a voltage transmission delay of the programmed word line.

### BACKGROUND

### Technical Field

The invention relates to a non-volatile memory and a program method thereof, and particularly relates to a non-volatile memory adapted to reduce a threshold voltage range of programmed memory cells and a program method thereof.

### Description of Related Art

In the conventional technical field, in a non-volatile memory, impedance of a word line may cause a certain voltage transmission delay. Therefore, during a process of a program operation, memory cells close to a front end of a voltage receiving end of the word line may receive a highly enough program voltage earlier than memory cells away from the front end of the voltage receiving end of the word line. Therefore, a program time of the memory cells at the front end is longer than a program time of the memory cells at the back end. Under such state, a distribution of threshold voltages of the programmed memory cells is dispersed and distributed over a wider range, which causes operational difficulties in erasing, reading operations, etc., of the memory cells, and makes the front end memory cells to be free from program disturbance.

### SUMMARY

The invention is directed to a non-volatile memory and a program method thereof, which are adapted to effectively reduce a distribution range of a threshold voltage of programmed memory cells.

The invention provides a program method of a non-volatile memory, and the program method includes: selecting a programmed word line, where the programmed word line has a plurality of segments respectively corresponding to a plurality of bit lines; providing a program voltage to a voltage receiving end of the programmed word line, and sequentially transmitting the program voltage to the segments; respectively providing a plurality of bit line voltages to the bit lines at a plurality of enable time points and turning on a string selection switch corresponding to the programmed word line at a setting time point; and setting voltage values of the bit line voltages according to the segments respectively corresponding to the bit lines, or setting the enable time points according to the segments respectively corresponding to the bit lines, or setting the setting time point according to a voltage transmission delay caused by the programmed word line.

The invention provides a non-volatile memory including a plurality of word lines, a plurality of bit lines, a plurality of source lines and a controller. Each of the word lines is coupled to a plurality of memory cell strings. The bit lines are respectively coupled to the memory cell strings. A string selection switch control line is respectively coupled to a plurality of string selection switches of the memory cell strings on the corresponding word line. The controller is coupled to the source lines, the bit lines and the word lines. The controller is configured to select a programmed word line having a plurality of segments, where the segments respectively correspond to a plurality of the bit lines; provide a program voltage to a voltage receiving end of the programmed word line, and sequentially transmit the program voltage to the segments; respectively provide a plurality of bit line voltages to the bit lines at a plurality of enable time points and turn on the string selection switches corresponding to the programmed word line at a setting time point; and set voltage values of the bit line voltages according to the segments respectively corresponding to the bit lines, or set the enable time points according to the segments respectively corresponding to the bit lines, or set the setting time point according to a voltage transmission delay caused by the programmed word line.

Based on the above description, the programmed word line is divided into a plurality of segments, and in an embodiment, by adjusting electrical characteristics of the bit line voltages, a time for the segments closer to the voltage receiving end executing the program operation of the corresponding memory cells is delayed, such that time lengths for the memory cells on the whole programmed word line executing the program operation are balanced. Alternatively, in another embodiment of the invention, a turn on time of the string selection switches of the memory cell strings is adjusted according to the voltage transmission delay caused by the programmed word line, which may also balance the time lengths for the memory cells on the programmed word line executing the program operation. In this way, the threshold voltage of the programmed memory cells of the embodiments of the invention is limited within a certain distribution range.

To make the aforementioned more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flowchart illustrating a program method of a non-volatile memory according to an embodiment of the invention.

FIG. 2A and FIG. 2B are respectively waveform diagrams of different implementations of the embodiment of the invention.

FIG. 3 is a schematic diagram of a program method of a non-volatile memory according to another embodiment of the invention.

FIG. 4A and FIG. 4B are schematic diagrams of distributions of threshold voltages of programmed memory cells generated under different implementations of the invention.

FIG. 5 is a waveform diagram of a program operation according to an embodiment of the invention.

FIG. 6A and FIG. 6B illustrate an influence of the program method of the embodiment of the invention on a inhibited bit line.

FIG. 7 is a waveform diagram of another implementation of the program method of the invention.

FIG. 8A and FIG. 8B are comparison diagrams of the implementation of FIG. 7 and the prior art.

FIG. 9 is a schematic diagram of a non-volatile memory according to an embodiment of the invention.

### DESCRIPTION OF THE EMBODIMENTS

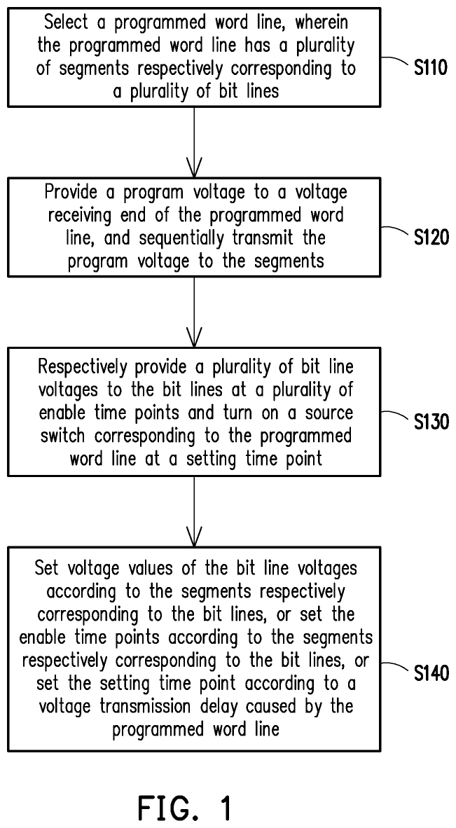

Referring to FIG. 1, FIG. 1 is a flowchart illustrating a program method of a non-volatile memory according to an embodiment of the invention. In FIG. 1, when a program operation of memory cells is performed, in a step S110, a programmed word line is selected, where the selected programmed word line has a plurality of segments, and the segments respectively correspond to a plurality of bit lines. Moreover, the programmed word line has a voltage receiving end. When the program operation is performed to the programmed word line, the voltage receiving end of the programmed word line may receive a program voltage. It should be noted that the plurality of segments and the voltage receiving end in the programmed word line respectively have a plurality of distances there between. In a step S120, the program voltage is provided to the voltage receiving end of the programmed word line, and the program voltage is sequentially transmitted to the segments.

It should be noted that a certain voltage transmission delay is provided based on each of the segments of the programmed word line, so that time points for transmitting the program voltage to the aforementioned segments are different. To be specific, the more the segment is closer to the voltage receiving end (a distance there between is shorter), the earlier the time point of receiving the program voltage is. Comparatively, the more the segment is away from the voltage receiving end, the later the time point of receiving the program voltage is.

In a step S130, a plurality of enable time points and a setting time points are set, and a plurality of bit line voltages is respectively provided to the bit lines at the plurality of enable time points, and a string selection switch corresponding to the programmed word line is turned on at the setting time point. In a step S140, in an embodiment of the invention, voltage values of the bit line voltages are set according to the segments respectively corresponding to the bit lines. Alternatively, in another embodiment of the invention, the enable time points are set according to the segments respectively corresponding to the bit lines. Alternatively, in still another embodiment of the invention, the setting time point is set according to a voltage transmission delay caused by the programmed word line.

Regarding an implementation detail of the step S140, in an embodiment of the invention, the setting operation of the bit line voltages is performed according to the segments corresponding to the bit lines. To be specific, the voltage values of the bit line voltages are set according to distances between the segments corresponding to the bit lines and the voltage receiving end of the programmed word line. When the distance between the segment corresponding to the bit line and the voltage receiving end of the programmed word line is closer, the voltage value of the bit line voltage of the bit line may be set to a relatively high voltage value. Namely, the voltage values of the bit line voltages are negatively correlated to the distances between the corresponding segments and the voltage receiving end.

It should be noted that based on the situation that the more the segment is closer to the voltage receiving end, the earlier the time point of receiving the program voltage is, by setting the voltage value of the received bit line voltage of the bit line high, the time point of performing the program operation on the memory cells of such segment may be delayed. By correspondingly setting the negatively correlated bit line voltages on the bit lines according to the distances with the voltage receiving end, the time points for programming the memory cells on the whole programmed word line are close to each other, and a distribution of the threshold voltages of the programmed memory cells may be limited within a certain distribution range. It should be noted that regarding the bit line corresponding to the last segment, the voltage value of the bit line voltage thereof may be 0 volt.

Regarding another implementation of the step S140, the enable time points of the bit line voltages may be set according to the segments corresponding to the bit lines. To be specific, the enable time points of the bit line voltages are set according to the distances between the segments corresponding to the bit lines and the voltage receiving end of the programmed word line. The closer the distance between the segment corresponding to the bit line and the voltage receiving end of the programmed word line is, the earlier the enable time point of the bit line voltage of the bit line may be set to. Moreover, at the enable time point, the corresponding bit line is applied with a non-zero bit line voltage. Namely, the enable time points of the bit line voltages are positively correlated to the distances between the corresponding segments and the voltage receiving end.

Similarly, based on the situation that the more the segment is closer to the voltage receiving end, the earlier the time point of receiving the program voltage is, by setting the enable time point of the received bit line voltage of the bit line to be earlier, the time point of performing the program operation on the memory cells of such segment may be delayed. By correspondingly setting the positively correlated enable time points of the bit line voltages on the bit lines according to the distances with the voltage receiving end, the time points for programming the memory cells on the whole programmed word line are close to each other, and a distribution of the threshold voltages of the programmed memory cells may be limited within a certain distribution range. It should be noted that regarding the bit line corresponding to the last segment, the voltage value of the bit line voltage thereof may be permanently maintained to 0 volt.

It should be noted that in the embodiment, after the enable time point, the bit line voltages on each of the bit lines may have a same voltage value, or may have different voltage values. After the enable time point, the bit line voltages on each of the bit lines may also be set in a negative correlation manner according to the distance between the corresponding segments and the voltage receiving end.

Regarding still another implementation of the step S140, a setting time point may be set according to the maximum voltage transmission delay provided by the programmed word line. The string selection switches of the memory cell strings corresponding to the programmed word line are turned on at the aforementioned setting time. The longer the voltage transmission delay provided by the programmed word line is, the latter the setting time point is set to. To be specific, by setting the setting time point, the string selection switches of the memory cell strings may be turned on together when the program voltage is effectively transmitted to the last segment in the programmed word line. In this way, all of the memory cells may execute the program operation at the same time point, and distribution of the threshold voltages of the programmed memory cells is limited within a certain distribution range.

It should be noted that in the embodiment, by applying a bias voltage to a control terminal of the string selection switch in the memory cell string at the enable time point, the string selection switch may be turned on at the setting time point.

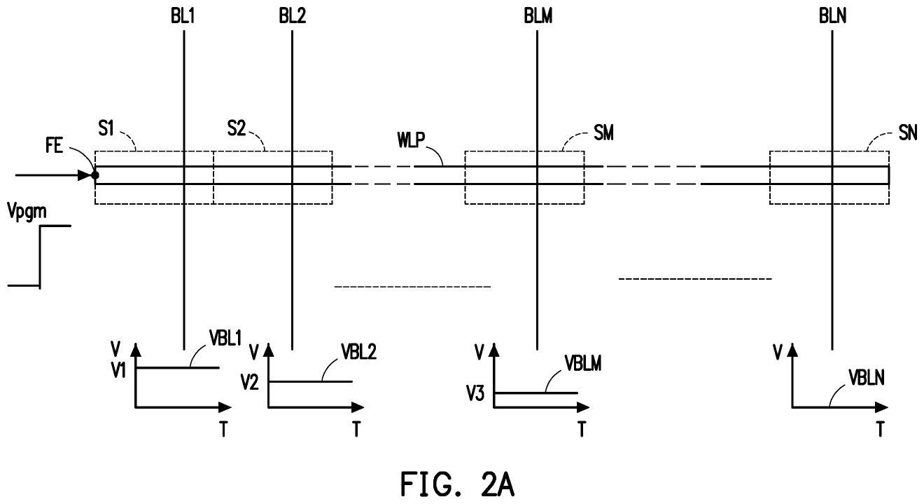

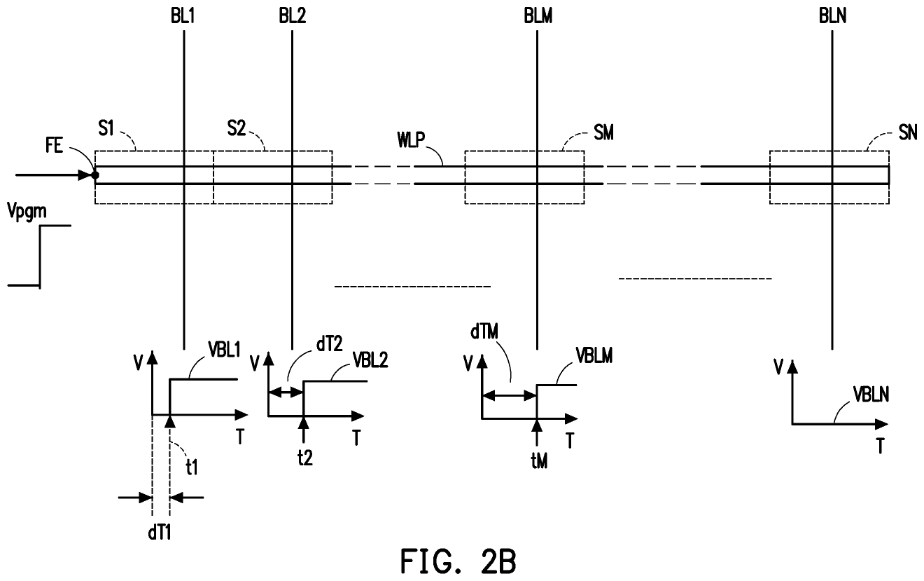

Referring to FIG. 2A and FIG. 2B, FIG. 2A and FIG. 2B are respectively waveform diagrams of different implementations of the embodiment of the invention. In FIG. 2A, the programmed word line WLp has a plurality of segments S1-SN arranged in a sequence, where a voltage receiving end FE is set on the segment S1. The segments S1-SN may be divided into front segments (the segments S1, S2), middle segments (the segment SM) and rear segments (the segment SN) according to distances between the segments S1-SN and the voltage receiving end FE. The segments S1-SN are respectively coupled to a plurality of bit lines BL1-BLN, where the bit lines BL1-BLN may be divided into front bit lines (the bit lines BL1, BL2), middle bit lines (the bit lines BLM) and back bit lines (the bit lines BLN).

During a process of the program operation, the voltage receiving end FE of the programmed word line WLp receives a program voltage Vpgm, and the bit lines BL1-BLN respectively receive bit line voltages VBL1-VBLN. In the waveform of the bit line voltages VBL1-VBLN, a horizontal axis represents time T, and a vertical axis represents voltage V. It should be noted that the more the bit lines BL1-BLN is corresponding to the segments S1-SN closer to the voltage receiving end FE, the larger the voltage values of the received bit line voltages VBL1-VBLN are. Namely, in the embodiment, VBL1>VBL2> . . . >VBLM> . . . >VBLN. Moreover, the bit line voltage VBLN may be 0 volt.

In FIG. 2B, during the process of the program operation, the voltage receiving end FE of the programmed word line WLp receives the program voltage Vpgm, and the bit lines BL1-BLN respectively receive the bit line voltages VBL1-VBLN according to different enable time points, where the bit line voltage VBL1 received by the bit line BL1 is raised to a non-zero bit line voltage at the enable time point t1; the bit line voltage VBL2 received by the bit line BL2 is raised to a non-zero bit line voltage at the enable time point t2; and the bit line voltage VBLM received by the bit line BLM is raised to a non-zero bit line voltage at the enable time point tM.

It should be noted that the bit line voltage VBLN received by the bit line BLN corresponding to the last segment SN is constantly 0 volt in the program operation.

In the embodiment, the bit line voltages VBL1-VBLM respectively have delay time dT1, dT2 and dTM with a start time point (an origin of the coordinate axes), where dT1<dT2< . . . <dTM.

It should be noted that the voltage values of the bit line voltages VBL1-VBLM may be the same or different after the enable time points.

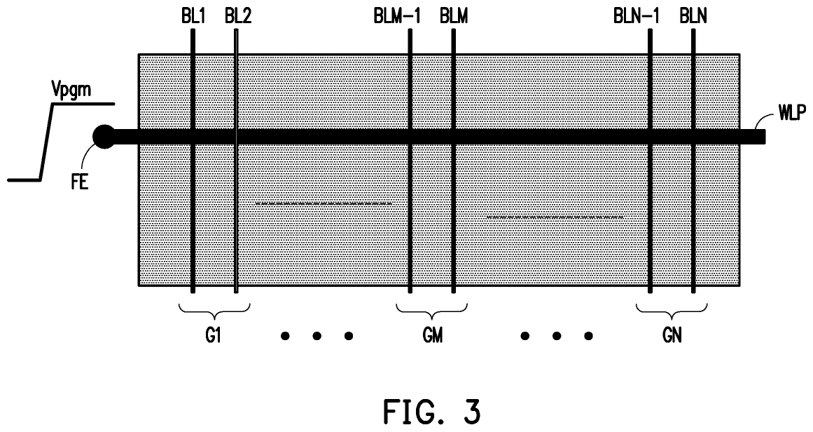

Referring to FIG. 3, FIG. 3 is a schematic diagram of a program method of a non-volatile memory according to another embodiment of the invention. In FIG. 3, in the programmed word line WLp, the plurality of bit lines BL1-BLN respectively corresponding to the plurality of segments may be grouped. The bit lines BL1-BLN may be grouped into a plurality of groups according to the distances with the voltage receiving end FE. In the embodiment, the bit lines BL1 and BL2 may be grouped into a group G1; the bit lines BLM−1 and BLM may be grouped into a group GM; and the bit lines BLN−1 and BLN may be grouped into a group GN. During the process of the program operation, the voltage receiving end FE receives the program voltage Vpgm, characteristics (voltage values or enable time points) of the bit line voltages applied to the same groups G1-GM may be the same. Moreover, characteristics (voltage values or enable time points) of the bit line voltages applied to the different groups G1-GM are different.

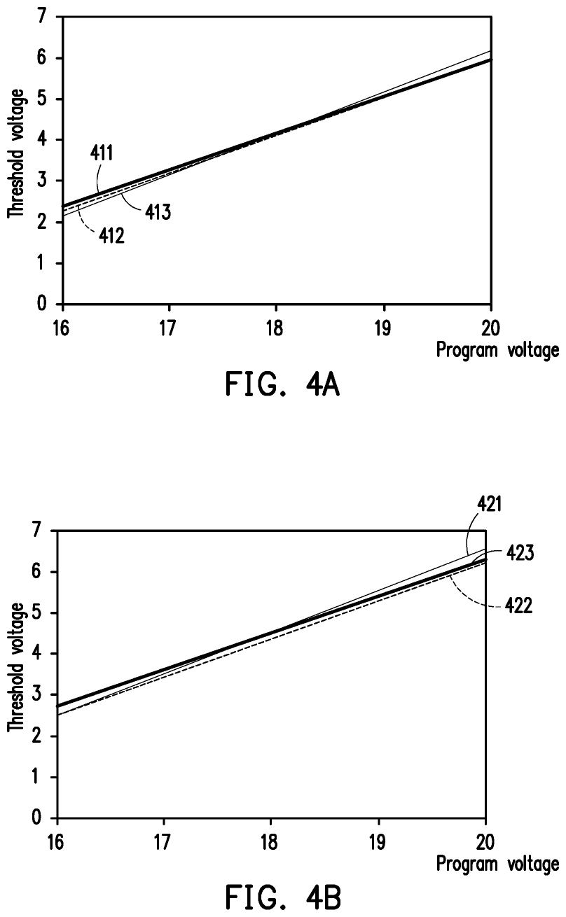

Referring to FIG. 4A and FIG. 4B, FIG. 4A and FIG. 4B are schematic diagrams of distributions of threshold voltages of the programmed memory cells generated under different implementations of the invention. In FIG. 4A, through an Incremental Step Pulse Programming (ISPP) operation, and through the method of adjusting the voltages values of the bit line voltages, in the programmed word line, a threshold voltage line 411 corresponding to the programmed memory cells of the front segment, a threshold voltage line 412 corresponding to the programmed memory cells of the middle segment, and a threshold voltage line 413 corresponding to the programmed memory cells of the rear segment are all raised along with increase of the accumulated program voltages, and the threshold voltage lines 411-413 are almost overlapped with each other, which represents that the threshold voltages of the programmed memory cells have a relatively small distribution range.

In FIG. 4B, through the ISPP operation, and through the method of adjusting the enable time points of the bit line voltages, in the programmed word line, a threshold voltage line 421 corresponding to the programmed memory cells of the front segment, a threshold voltage line 422 corresponding to the programmed memory cells of the middle segment, and a threshold voltage line 423 corresponding to the programmed memory cells of the rear segment are all raised along with increase of the accumulated program voltages, and the threshold voltage lines 421-423 are almost overlapped with each other, which represents that the threshold voltages of the programmed memory cells have a relatively small distribution range.

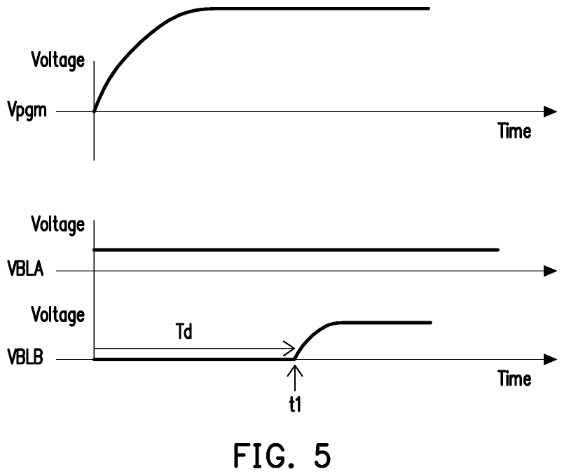

Referring to FIG. 5, FIG. 5 is a waveform diagram of a program operation according to an embodiment of the invention. In FIG. 5, when the program operation is executed, the programmed word line receives the program voltage Vpgm raised along with time. Accordingly, in a first implementation of the invention, in the program operation, by setting different bit lines to have different bit line voltages VBLA to adjust program time points of the programmed memory cells on the programmed word line, and making the program time points of the programmed memory cells to be substantially the same, an effect of controlling the distribution range of the threshold voltages of the programmed memory cells is achieved. In a second implementation of the invention, by setting the enable time point t1 of the bit line voltages VBLB of different bit lines, and adjusting a delay time Td that the bit line voltage VBLB is pulled up to the non-zero voltage value to adjust the program time points of the programmed memory cells on the programmed word line, and making the program time points of the programmed memory cells to be substantially the same, the effect of controlling the distribution range of the threshold voltages of the programmed memory cells is also achieved.

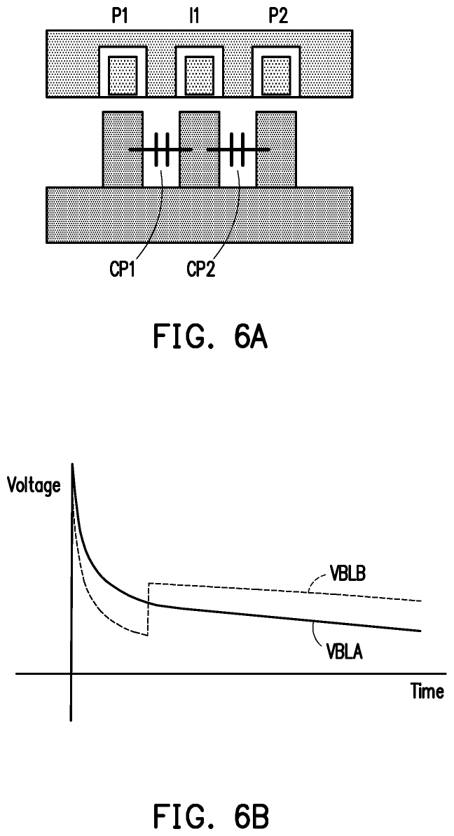

Referring to FIG. 6A and FIG. 6B, FIG. 6A and FIG. 6B illustrate an influence of the program method of the embodiment of the invention on an inhibited bit line. In FIG. 6A, if adjacent three memory cells are sequentially a programmed memory cell P1, an inhibited memory cell I1 and a programmed memory cell P2, in order to effectively shield the inhibited memory cell I1, the bit line voltage of the bit line corresponding to the inhibited memory cell I1 should be pulled high. However, as the programmed memory cells P1 and P2 are located adjacent to two sides of the inhibited memory cell I1, parasitic capacitances CP1 and CP2 formed there between may weaken the pull-high effect of the bit line voltage corresponding to the inhibited memory cell I1. According to the two implementations of the invention, the bit line voltage VBLA may be pulled high (as shown in FIG. 6B), or the voltage value of the bit line voltage VBLB may be pulled high at the enable time point (as shown in FIG. 6B), which avails the pull-high operation of the bit line voltage corresponding to the shielding memory cell I1, and improving a shielding effect of the inhibited memory cell I1.

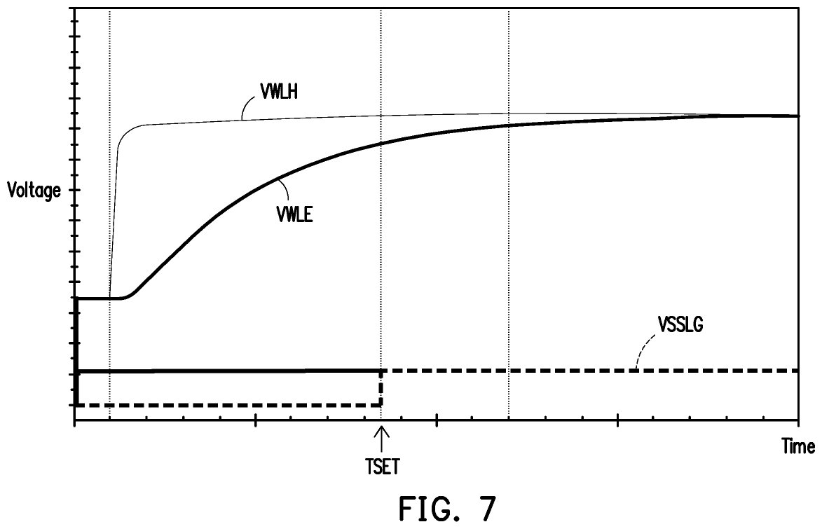

Referring to FIG. 7, FIG. 7 is a waveform diagram of another implementation of the program method of the invention. In the program operation, the program voltage is provided to the programmed word line, and is sequentially transmitted to a plurality of the segments of the programmed word line, where the front segment receives a program voltage VWLH, and the rear segment receives a program voltage VWLE. It is discovered that a time point when the program voltage VWLE is raised to a highly enough voltage level to execute the program operation is later than a time point when the program voltage VWLH is raised to a highly enough voltage level to execute the program operation.

Corresponding to the above state, in another implementation of the invention, a setting time point TSET may be set according to the time point when the program voltage VWLE is raised to the highly enough voltage level to execute the program operation. At the setting time point TSET, by pulling high the bias voltage on the control terminal of the string selection switch, the string selection switch is turned on at the setting time point TSET. In this way, all of the programmed memory cells may start executing the program operation at the setting time point TSET, which improves uniformity of the threshold voltages thereof.

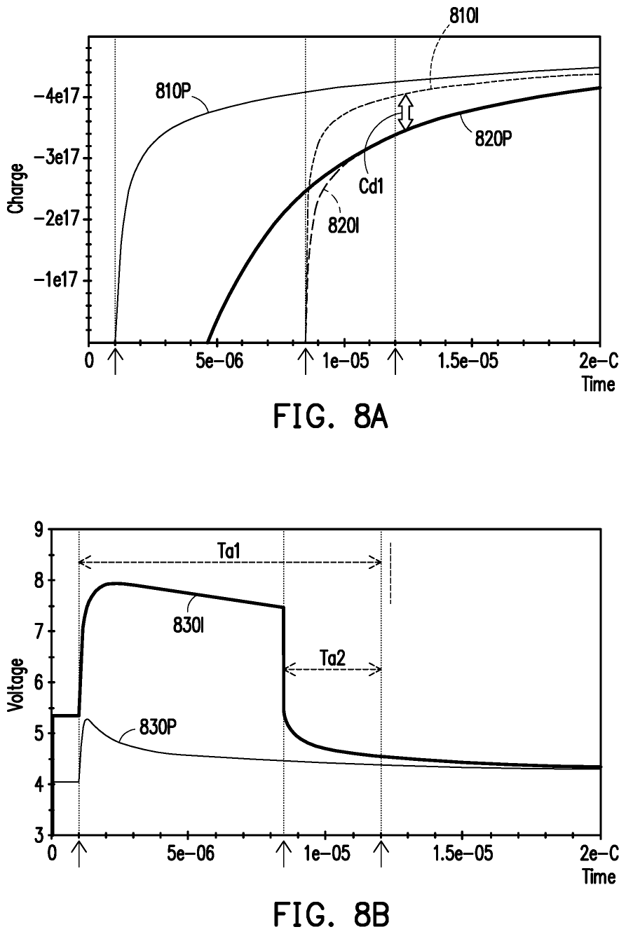

Referring to FIG. 8A and FIG. 8B, FIG. 8A and FIG. 8B are comparison diagrams of the implementation of FIG. 7 and the prior art. The prior art refers to that a turn-on time of the string selection switch is not adjusted, and the string selection switch maintains a constant turned-on state during the program operation. In FIG. 8A, a curve 810P represents a variation of a charge amount of the memory cells of the front segment along with time during the program operation in the prior art; a curve 820P represents a variation of a charge amount of the memory cells of the rear segment along with time during the program operation in the prior art; a curve 8101 represents a variation of a charge amount of the memory cells of the front segment along with time during the program operation in the implementation of FIG. 7; and a curve 8201 represents a variation of a charge amount of the memory cells of the rear segment along with time during the program operation in the implementation of FIG. 7. According to FIG. 8A, it is clearly known that based on the implementation of FIG. 7, a difference Cd1 between the charge amounts in the programmed memory cells of the front segment and the rear segment can be lower.

In FIG. 8B, a curve 830P represents a variation of a boosted channel voltage; and a curve 8301 represents a variation of the voltages of the programmed memory cells in the implementation of FIG. 7. The program operation of the prior art is executed and completed within a time interval ta1, and the program operation of the implementation of FIG. 7 is completed within a time interval ta2.

According to the description above, the operation scheme does not reduce a boosted channel potential of the memory cell. Such as that, a program disturbance is not effected by applying the operation scheme of present embodiment.

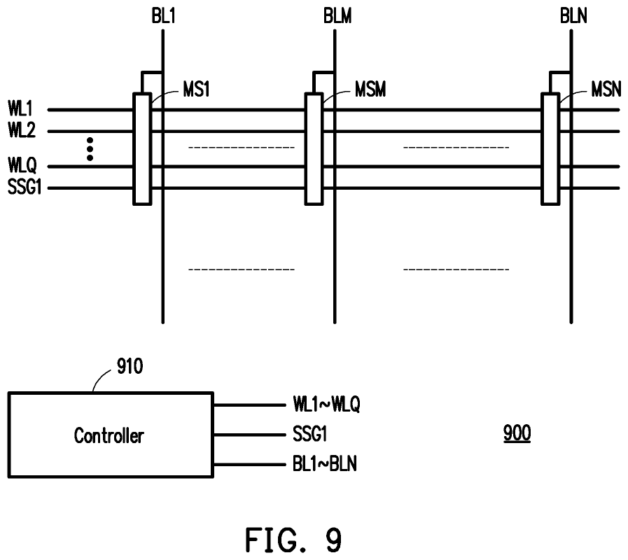

Referring to FIG. 9, FIG. 9 is a schematic diagram of a non-volatile memory according to an embodiment of the invention. The non-volatile memory 900 includes a plurality of word lines WL1-WLQ, a plurality of bit lines BL1-BLN, a string selection switch control line SSG1 and a controller 910. The word lines WL1-WLQ are coupled to a plurality of memory cell strings MS1-MSN. The bit lines BL1-BLN are respectively coupled to the memory cell strings MS1-MSN. The string selection switch control line SSG1 is coupled to a plurality of string selection switches of the memory cell strings MS1-MSN. The controller 910 is coupled to the string selection switch control line SSG1, the bit lines BL1-BLN and the word lines WL1-WLQ. The controller 910 is configured to execute the steps of the program method shown in FIG. 1 to control the distribution range of the threshold voltages of the programmed memory cells.

Details for the controller 910 executing the program method have been introduced in the aforementioned embodiments and implementations, and details thereof are not repeated.

In the embodiments, the controller 910 may be a processor with a commutation power. Alternatively, the controller 910 may be a hardware circuit designed through a Hardware Description Language (HDL) or any other digital circuit design method well known by those skilled in the art, and implemented through a Field Programmable Gate Array (FPGA), a Complex Programmable Logic Device (CPLD) or an Application-Specific Integrated Circuit (ASIC), which is not limited by the invention.

In summary, regarding the plurality of segments in the programmed word line, by delaying a program time of the memory cells of the front segment, the program operations of the memory cells of all of the segments on the programmed word line may be executed at a closed time point, so as to improve uniformity of the threshold voltages of the programmed memory cells. Alternatively, in the embodiment of the invention, by controlling the turning on operation of the string selection switch, the program operations of the memory cells of all of the segments on the programmed word line are controlled. A turn-on time point of the string selection switch is set according to the voltage transmission delay of the programmed word line, such that the program operations of the memory cells of all of the segments on the programmed word line may be executed at the closed time point, which may also improve the uniformity of the threshold voltages of the programmed memory cells.

It will be apparent to those skilled in the art that various modifications and variations can be made to the disclosed embodiments without departing from the scope or spirit of the invention. In view of the foregoing, it is intended that the invention covers modifications and variations provided they fall within the scope of the following claims and their equivalents.

1. A program method of a non-volatile memory, comprising:
selecting a programmed word line, wherein the programmed word line has a plurality of segments respectively corresponding to a plurality of bit lines;
providing a program voltage to a voltage receiving end of the programmed word line, and sequentially transmitting the program voltage to the segments;
respectively providing a plurality of bit line voltages to the bit lines at a plurality of enable time points and turning on a string selection switch corresponding to the programmed word line at a setting time point; and
setting the enable time points according to the segments respectively corresponding to the bit lines, or setting the setting time point according to a voltage transmission delay caused by the programmed word line.

2. The program method of the non-volatile memory as claimed in claim 1, wherein the segments and the voltage receiving end respectively have a plurality of distances there between.

3-4. (canceled)

5. The program method of the non-volatile memory as claimed in claim 2, wherein the enable time points are respectively set according to the corresponding distances.

6. The program method of the non-volatile memory as claimed in claim 5, wherein the enable time points are negatively correlated with the corresponding distances.

7. (canceled)

8. The program method of the non-volatile memory as claimed in claim 1, further comprising:
dividing the segments into a plurality of segment groups, wherein each of the segment groups comprises at least one of the segments; and
dividing the bit lines into a plurality of bit line groups corresponding to the segment groups, wherein each of the bit line groups comprises at least one of the bit lines,
wherein the enable time points of the bit line voltages of the same bit line group are the same, and the enable time points of the bit line voltages of different bit line groups are different.

9. The program method of the non-volatile memory as claimed in claim 8, wherein the numbers of the bit lines included in each of the bit line groups are completely the same, completely different or partially same.

10. The program method of the non-volatile memory as claimed in claim 1, wherein a magnitude of the voltage transmission delay caused by the programmed word line is negatively correlated to the enable time points.

11. A non-volatile memory, comprising:
a plurality of word lines, each of the word lines being coupled to a plurality of memory cell strings;
a plurality of bit lines, respectively coupled to the memory cell strings;
a string selection switch control line, coupled to a plurality of string selection switches of the memory cell strings; and
a controller, coupled to the string selection switch control line, the bit lines and the word lines, and configured to:
select a programmed word line having a plurality of segments, wherein the segments respectively correspond to the bit lines;
provide a program voltage to a voltage receiving end of the programmed word line, and sequentially transmit the program voltage to the segments;
respectively provide a plurality of bit line voltages to the bit lines at a plurality of enable time points, and turn on each of the string selection switches corresponding to the programmed word line at a setting time point; and
set the enable time points according to the segments respectively corresponding to the bit lines, or set the setting time point according to a voltage transmission delay caused by the programmed word line.

12. The non-volatile memory as claimed in claim 11, wherein the segments and the voltage receiving end respectively have a plurality of distances there between.

13-14. (canceled)

15. The non-volatile memory as claimed in claim 12, wherein the enable time points are respectively set according to the corresponding distances.

16. The non-volatile memory as claimed in claim 15, wherein the enable time points are negatively correlated with the corresponding distances.

17. (canceled)

18. The non-volatile memory as claimed in claim 11, wherein the controller is further configured to:
divide the segments into a plurality of segment groups, wherein each of the segment groups comprises at least one of the segments; and
divide the bit lines into a plurality of bit line groups corresponding to the segment groups, wherein each of the bit line groups comprises at least one of the bit lines,
wherein the enable time points of the bit line voltages of the same bit line group are the same, and the enable time points of the bit line voltages of different bit line groups are different.

19. The non-volatile memory as claimed in claim 18, wherein the numbers of the bit lines included in each of the bit line groups are completely the same, completely different or partially same.

20. The non-volatile memory as claimed in claim 11, wherein a magnitude of the voltage transmission delay caused by the programmed word line is negatively correlated to the enable time points.
